(19) United States
(12) Patent Application Publication
(10) Pub. No.: US 2012/0318561 A1
(43) Pub. Date: Dec. 20, 2012

(54) PATTERN FORMATION METHOD, METHOD FOR MANUFACTURING ELECTRONIC DEVICE, AND ELECTRONIC DEVICE

(76) Inventors: Kazuhiro TAKAHATA, Kanagawa-ken (JP); Masafumi Asano, Kanagawa-ken (JP); Yingkang Zhang, Kanagawa-ken (JP); Tomoko Ojima, Tokyo (JP)

(21) Appl. No.: 13/424,112

(22) Filed: Mar. 19, 2012

(30) Foreign Application Priority Data
Jun. 15, 2011 (JP) 2011-133290

(51) Int. Cl. H05K 3/00; H05K 1/00

(52) U.S. Cl. 174/250; 29/829

(57) ABSTRACT

According to one embodiment, a pattern formation method includes: providing a first member; providing a second member; forming a third pattern; and removing a convex portion of a second pattern. The first member is provided on a major surface of a substrate and cured in a state of a template having a first pattern being brought into contact to form the second pattern including a convex portion in a first region on the major surface. The second member is provided in a concave portion adjacent to the convex portion of the second pattern. The third pattern is formed in the second member provided on a second region on the major surface. The removing the convex portion includes removing the convex portion of the second pattern to leave the third pattern and a fourth pattern formed by the second member provided in the concave portion on the major surface.

### CROSS-REFERENCE TO RELATED APPLICATIONS

This application is based upon and claims the benefit of priority from the prior Japanese Patent Application No. 2011-133290, filed on Jun. 15, 2011; the entire contents of which are incorporated herein by reference.

### FIELD

Embodiments described herein relate generally to a pattern formation method, a method for manufacturing electronic device, and an electronic device.

### BACKGROUND

In the manufacturing of semiconductor products, a circuit pattern is formed on a wafer of silicon or the like, and then semiconductor products are separated from the wafer to form rectangular chips. Therefore, a portion that does not form rectangular chips (hereinafter referred to as a “partial chip portion”) is formed in the peripheral portion of the circular wafer. In view of the influence on manufacturing processes, a pattern formed by using a resist etc. is preferably provided also in the partial chip portion. That is, if the coverage ratio that depends on the pattern of the product chip portion and the partial chip portion is greatly different, uniformity may be affected by this in a subsequent etching process and CMP (chemical mechanical polishing) process etc.

Here, in the pattern formation by optical lithography, exposure is performed also on the partial chip portion to form a pattern of a resist etc. On the other hand, in the pattern formation by what is called the imprint method in which the concavo-convex pattern of a template is attached to a resin (resist etc.) on a wafer to form a concavo-convex pattern, it is difficult to form a pattern in the partial chip portion. Therefore, in what is called the imprint method, highly reliable pattern formation including the processing on the partial chip portion is desired.

### BRIEF DESCRIPTION OF THE DRAWINGS

FIG. 1 is a flow chart describing the flow of a pattern formation method according to a first embodiment;

FIGS. 2A to 2F are schematic cross-sectional views describing the pattern formation method according to the first embodiment in order;

FIG. 3A is a schematic plan view of the entire substrate, and FIG. 3B is a schematic enlarged plan view of an A portion of FIG. 3A;

FIG. 4 is a flow chart describing the flow of a pattern formation method according to a second embodiment; and

FIG. 5A to FIG. 13B are schematic views describing the second embodiment.

### DETAILED DESCRIPTION

In general, according to one embodiment, a pattern formation method includes: providing a first member on a major surface of a substrate and curing the first member in a state of a template having a first pattern being brought into contact with the first member to form a second pattern including a convex portion with a configuration inverse to a configuration of the first pattern in a first region on the major surface; providing a second member in a concave portion adjacent to a convex portion of the second pattern on the major surface and in a second region around the first region; forming a third pattern in the second member provided in the second region on the major surface; and removing the convex portion of the second pattern to leave the third pattern and a fourth pattern formed by the second member provided in the concave portion on the major surface.

In general, according to another embodiment, a method for manufacturing an electronic device includes: forming a pattern using a pattern formation method including: providing a first member on a major surface of a substrate and curing the first member in a state of a template having a first pattern being brought into contact with the first member to form a second pattern including a convex portion with a configuration inverse to a configuration of the first pattern in a first region on the major surface; providing a second member in a concave portion adjacent to a convex portion of the second pattern on the major surface and in a second region around the first region; forming a third pattern in the second member provided in the second region on the major surface; and removing the convex portion of the second pattern to leave the third pattern and a fourth pattern formed by the second member provided in the concave portion on the major surface.

In general, according to another embodiment, an electronic device includes: a pattern formed using a pattern formation method including: providing a first member on a major surface of a substrate and curing the first member in a state of a template having a first pattern being brought into contact with the first member to form a second pattern including a convex portion with a configuration inverse to a configuration of the first pattern in a first region on the major surface; providing a second member in a concave portion adjacent to a convex portion of the second pattern on the major surface and in a second region around the first region; forming a third pattern in the second member provided in the second region on the major surface; and removing the convex portion of the second pattern to leave the third pattern and a fourth pattern formed by the second member provided in the concave portion on the major surface.

Hereinbelow, embodiments of the invention are described based on the drawings.

The drawings are schematic or conceptual; and the relationships between the thickness and width of portions, the proportional coefficients of sizes among portions, etc., are not necessarily the same as the actual values thereof. Further, the dimensions and proportional coefficients may be illustrated differently among drawings, even for identical portions.

In the specification of this application and the drawings, components similar to those described in regard to a drawing thereinabove are marked with the same reference numerals, and a detailed description is omitted as appropriate.

### First Embodiment

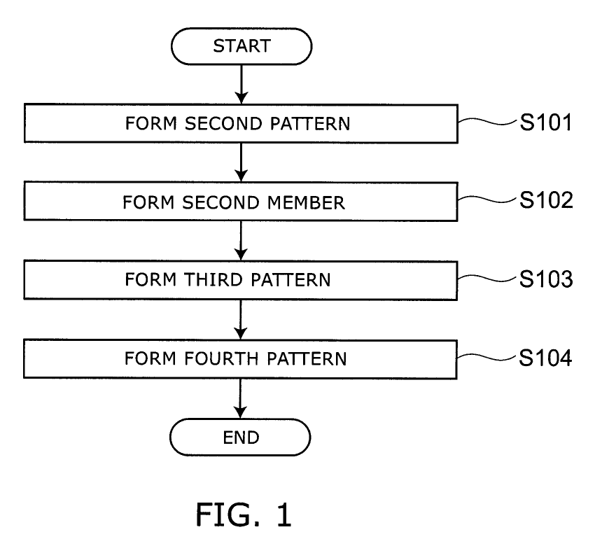

FIG. 1 is a flow chart describing the flow of a pattern formation method according to a first embodiment.

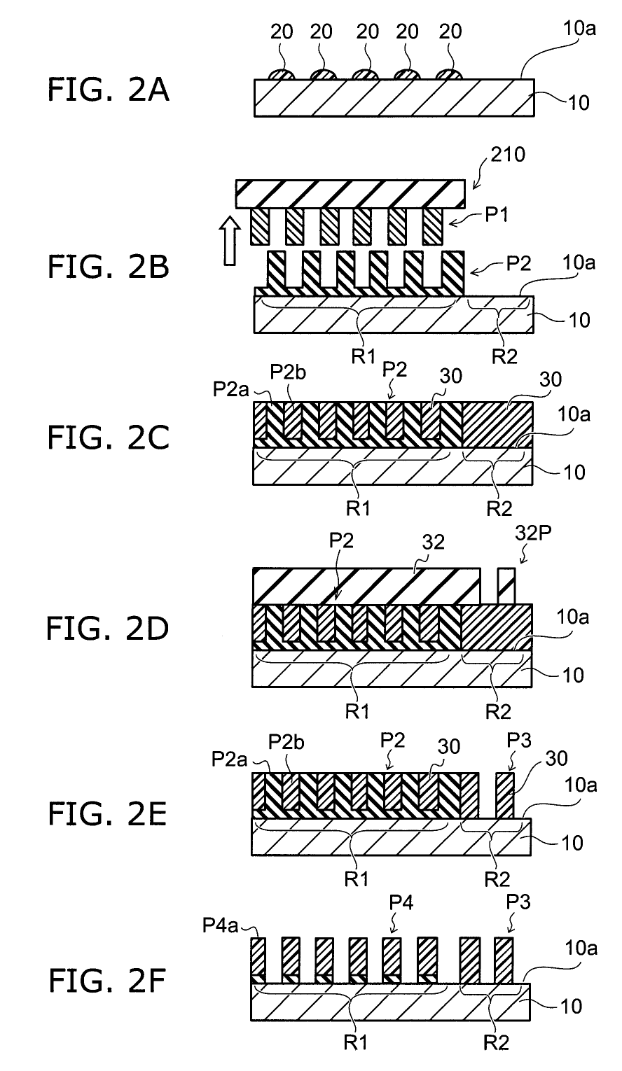

FIGS. 2A to 2F are schematic cross-sectional views describing the pattern formation method according to the first embodiment in order.

As shown in FIG. 1, the pattern formation method according to the first embodiment includes step S101 that forms a second pattern, step S102 that forms a second member, step S103 that forms a third pattern, and step S104 that forms a fourth pattern.

FIG. 2A and FIG. 2B illustrate states where the processing of step S101 is performed. FIG. 2C illustrates a state where the processing of step S102 is performed. FIG. 2D and FIG. 2E illustrate states where the processing of step S103 is performed. FIG. 2F illustrates a state where the processing of step S104 is performed.

In step S101, first, a first member (a resin 20) is provided on the major surface 10a of a substrate 10 (see FIG. 2A). Next, a template 210 is brought into contact with the first member to transfer the configuration of a first pattern P1 provided in the template 210. Then, the first member is cured in a state where the configuration of the first pattern P1 has been transferred to the first member. Thereby, a second pattern P2 having convex portions with a configuration inverse to the configuration of the first pattern P1 is formed in the first member. The second pattern P2 is formed in a first region R1 on the major surface 10a of the substrate 10 (see FIG. 2B).

In step S102, a second member 30 is provided on/above the major surface 10a of the substrate 10. The second pattern P2 has been formed on the major surface 10a of the substrate 10. The second member 30 is provided in a concave portion P2b adjacent to a convex portion P2a of the second pattern P2 and in a second region R2 around the first region R1. Specifically, the second member 30 is embedded in the concave portion P2b of the second pattern P2. The second member 30 is provided also in the second region R2 that is an area surrounding the first region R1 in which the second pattern P2 is formed. In other words, the second pattern P2 is in a state of being embedded in the second member 30 on the major surface 10a of the substrate 10 (see FIG. 2C).

In step S103, a third pattern P3 is formed in the second member 30 provided in the second region R2. The second member 30 has been provided in the second region R2 on the major surface 10a of the substrate 10. The third pattern P3 is formed in the second member 30 in the second region R2. For example, a resist film 32 is formed on the second member 30, and a resist pattern 32P corresponding to the configuration of the third pattern P3 is formed in a portion of the resist film 32 above the second region R2 by photolithography and etching (see FIG. 2D). After that, the resist pattern 32P is used as a mask to etch the second member 30. Thereby, the second pattern embedded in the second member remains in the first region R1 covered with the resist film 32, and the second region R2 becomes a state where the third pattern P3 formed by the second member 30 is provided (see FIG. 2E).

In step S104, the convex portion P2a of the second pattern P2 in the first region R1 is removed. When the convex portion P2a of the second pattern P2 has been removed, the second member 30 embedded in the concave portion P2b of the second pattern P2 remains as a convex pattern. The convex pattern forms a fourth pattern P4. Thereby, the fourth pattern P4 is provided in the first region R1 on the major surface 10a of the substrate 10, and the third pattern P3 is provided in the second region R2 (see FIG. 2F). The fourth pattern P4 is the pattern configuration of the objective. The third pattern P3 is formed around the fourth pattern P4. The third pattern P3 is a pattern formed in the partial pattern portion. That is, the fourth pattern P4 that is the pattern configuration of the objective can be formed, and further the third pattern P3 can be formed in the peripheral partial pattern portion.

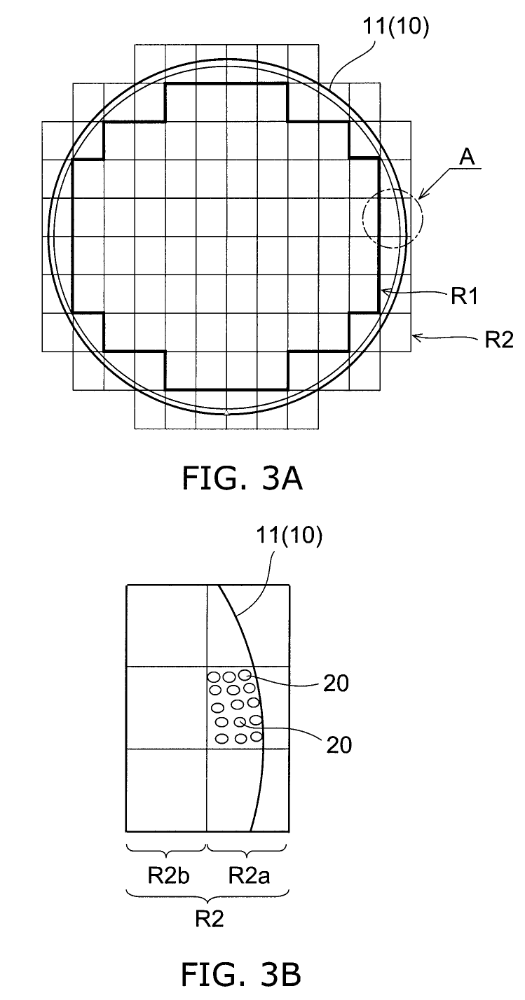

FIGS. 3A and 3B are schematic plan views describing the first region and the second region of the substrate.

FIG. 3A is a schematic plan view of the entire substrate. FIG. 3B is a schematic enlarged plan view of an A portion of FIG. 3A.

As shown in FIG. 3A, a circular wafer 11 is used as the substrate 10. One rectangle shown in FIG. 3A is a pattern formation region of one time (one shot) in optical lithography or what is called imprinting. A pattern for at least one chip is included in one shot. In the embodiment, a pattern for a plurality of chips is formed by one shot. Since one shot is a rectangle, the entire pattern of one shot is formed in the central portion of the circular wafer 11. The region where the entire pattern of one shot is formed is the first region R1. From the first region R1, chips effective as products can be extracted from the entire region of one shot.

On the other hand, in the peripheral portion of the wafer 11, only part of the pattern of one shot is formed. The region in which only part of the pattern of one shot is formed is the second region R2. What is included in the second region R2 is the partial chip portion that will not form effective chips.

In the pattern formation by what is called the imprint method, the concavo-convex pattern of a template is attached to a resin applied onto a substrate, and the configuration of the concavo-convex pattern is transferred to the resin.

Here, as shown in FIG. 3B, one shot in the second region R2 includes the partial chip portion (a region R2a) overlapping with the edge portion of the wafer 11 and the effective chip portion (a region R2b) not overlapping with the edge portion of the wafer 11. In the case where it is attempted to transfer a concavo-convex pattern to the region R2a using a template, the resin 20 applied to the region R2a spreads along the major surface due to the adhesion of the template. Since the edge of the wafer 11 exists in the region R2a, the spread resin 20 leaks to the outside of the wafer 11.

When the resin 20 is cured, there is a high possibility that the resin 20 that has leaked to the outside of the wafer 11 will become dust. In a state where dust is adhering to the template in contact with the edge portion of the wafer 11, if imprinting is subsequently performed on the shots that form the entire first region R1 in the inner portion of the wafer 11, there is a high possibility that a desired pattern will not be formed due to the influence of the dust adhering to the template. In order not to produce such dust, the pattern formation by what is called the imprint method may not be performed on the region R2a.

In the embodiment, in the first region R1 and the effective chip portion (the region R2b) in the second region R2, the pattern formation by what is called the imprint method is used to form a finer pattern than in the case where pattern formation is performed by optical lithography. On the other hand, in the partial chip portion (the region R2a) of the second region R2, the pattern formation using optical lithography is performed. Thereby, a fine pattern is formed in the first region R1 by what is called the imprint method, and a pattern can be formed also in the second region R2.

In the stage where the processing of step S104 shown in FIG. 1 has been finished, the coverage ratio of the pattern formed in the second region R2 is preferably equal to the coverage ratio of the pattern formed in the first region R1. The coverage ratio refers to the proportion of the area of the convex pattern per unit area. By making the coverage ratio in the second region R2 equal to the coverage ratio in the first region R1, uniformity can be increased in a subsequent etching process and a process such as CMP. Here, the range in which the coverage ratio is equal includes the range in which sufficient uniformity (for example, enough uniformity not to have an influence on the characteristics of products formed) can be obtained in the processes after a pattern is formed in the first region R1 and the second region R2.

Thus, in the embodiment, a pattern can be formed not only in the first region R1 but also in the second region R2, and a highly reliable product can be manufactured in which the uniformity of the underlayer is ensured in an etching process and a process such as CMP performed after pattern formation.

### Second Embodiment

In a second embodiment, a specific example of the pattern formation method is described.

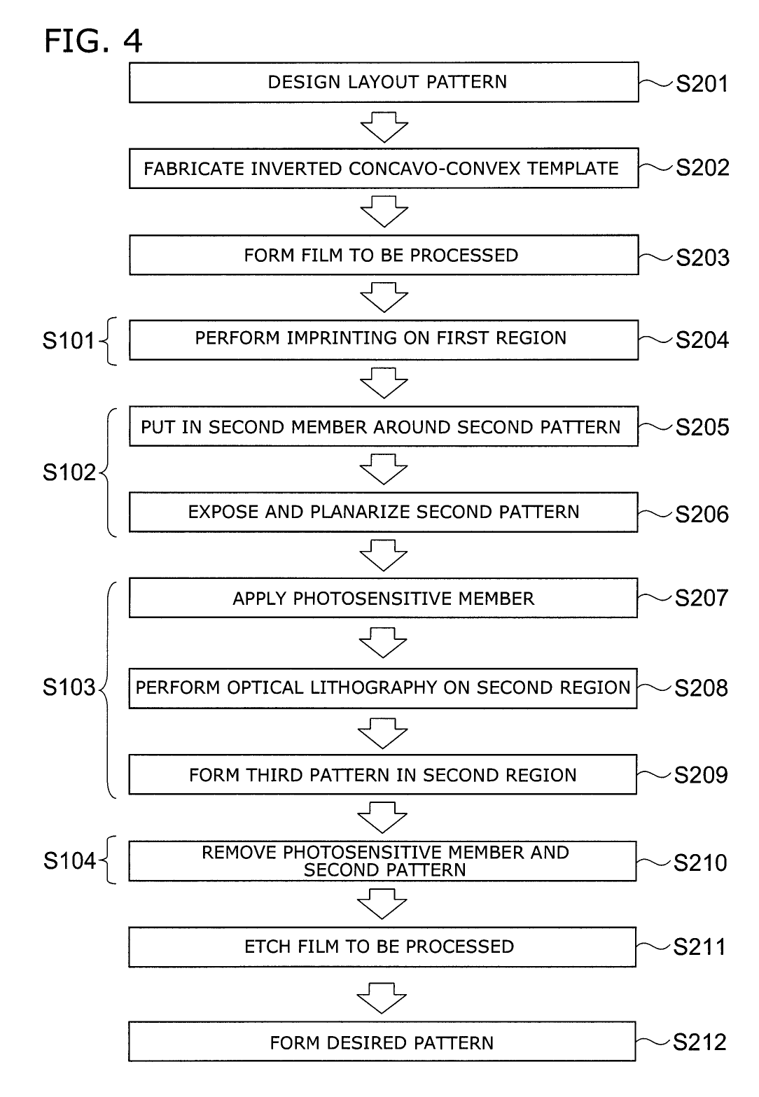

FIG. 4 is a flow chart describing the flow of a pattern formation method according to the second embodiment.

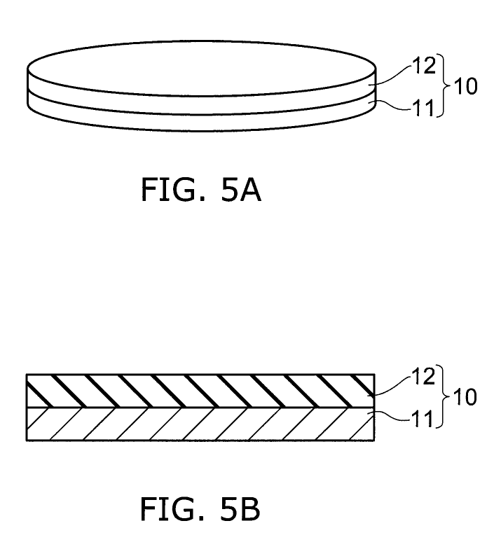

FIG. 5A to FIG. 13B are schematic views describing the second embodiment.

Here, step S204 shown in FIG. 4 corresponds to step S101 shown in FIG. 1. Steps S205 to S206 shown in FIG. 4 correspond to step S102 shown in FIG. 1. Steps S207 to S209 shown in FIG. 4 correspond to step S103 shown in FIG. 1. Step S210 shown in FIG. 4 corresponds to step S104 shown in FIG. 1.

A specific example of the pattern formation method will now be described in order with reference to FIG. 4 and FIG. 5A to FIG. 13B.

First, as shown in step S201 of FIG. 4, a layout pattern to be formed is designed. Then, as shown in step S202 of FIG. 4, a template with an inverted concavo-convex configuration is fabricated. The template is a plate used in the pattern formation by what is called the imprint method. A template in common imprint methods includes a pattern in which the concavo-convex configuration of a layout pattern to be formed is inverted. In the embodiment, a template is fabricated in which the concavo-convex configuration of the pattern is inverse to that of the template used in common imprint methods. The pattern of the template used in the embodiment is assumed to be the first pattern P1. The concavo-convex configuration of the first pattern P1 is the same as the concavo-convex configuration of the layout pattern to be formed.

Next, as shown in step S203 of FIG. 4 and FIGS. 5A and 5B, a film to be processed 12 is formed in the substrate 10.

FIG. 5A is a schematic perspective view, and FIG. 5B is a schematic cross-sectional view.

First, the substrate 10 is prepared. The substrate 10 includes the wafer 11 that forms an underlayer substrate and the film to be processed 12 formed on the wafer 11. In the case where the wafer 11 is used as an object to be processed, the film to be processed 12 is not formed. The wafer 11 is, for example, silicon. The film to be processed 12 is, for example, a silicon oxide film.

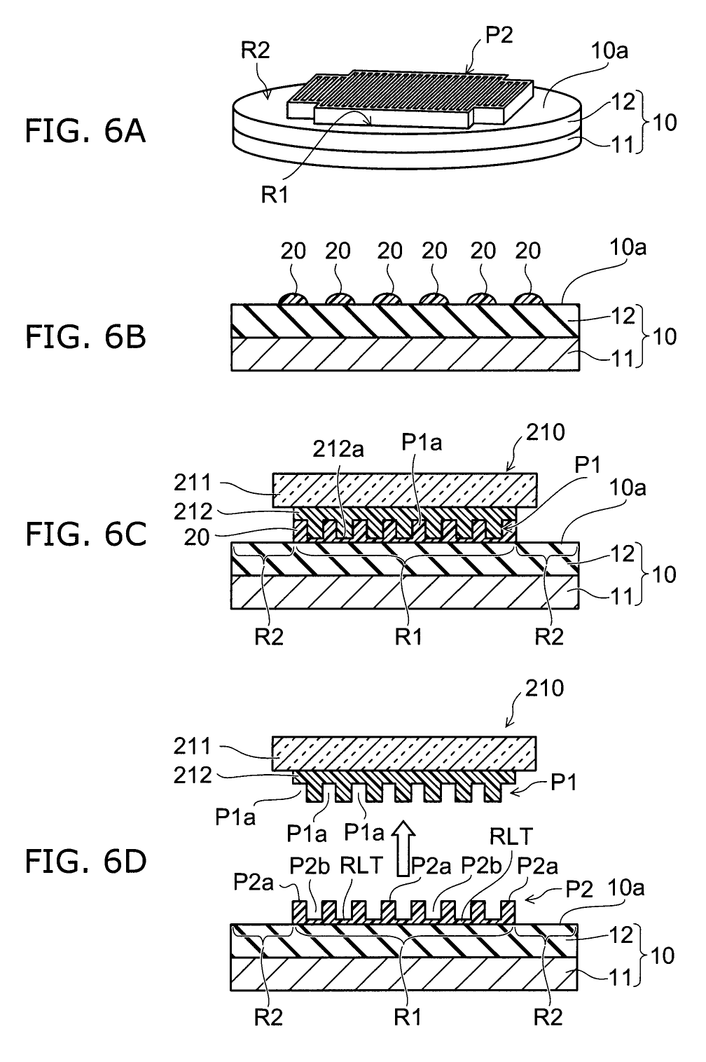

Next, as shown in step S204 of FIG. 4 and FIGS. 6A to 6D, what is called imprinting is performed on the first region R1 to form the second pattern P2.

FIG. 6A is a schematic perspective view, and FIGS. 6B to 6D are schematic cross-sectional views describing the formation processes for the second pattern in order.

That is, as shown in FIG. 6A, the second pattern P2 is formed in the first region R1 of the major surface 10a of the substrate 10.

The formation processes for the second pattern P2 will now be described in accordance with FIGS. 6B to 6D.

First, as shown in FIG. 6B, the resin (the first member) 20 is applied to the major surface 10a of the substrate 10. A photocurable resin, for example, is used as the resin 20. An appropriate amount of resin 20 is applied onto the major surface 10a. The resin 20 is, for example, dropped onto a plurality of places of the major surface 10a.

Next, as shown in FIG. 6C, the template 210 previously fabricated is prepared. The template 210 includes a base substrate 211 and a pattern unit 212 provided on the base substrate 211. The first pattern P1 is formed in the pattern unit 212. The pattern unit 212 is formed of, for example, a resin. The template 210 is formed by, for example, transferring the configuration of a master pattern (not shown) to the pattern unit 212 made of a resin. The concavo-convex configuration of the first pattern P1 corresponds to the concavo-convex configuration of the pattern to be formed.

Then, the pattern unit 212 of the template 210 is brought into contact with the resin 20 provided on the major surface 10a of the substrate 10. At this time, a small space (for example, of several nanometers (nm)) is provided between the end 212a of the pattern unit 212 and the major surface 10a of the substrate 10. The resin 20 enters a concave portion P1a of the first pattern P1 due to capillarity, and is put therein.

Next, the resin 20 is cured in this state. For example, the resin 20 is irradiated with ultraviolet light via the base substrate 211 of the template 210. The ultraviolet light is transmitted through the base substrate 211 and the pattern unit 212 and applied to the resin 20. The resin 20 made of a photocurable resin is cured by being irradiated with the ultraviolet light.

Next, as shown in FIG. 6D, the template 210 is removed. Thereby, the second pattern P2 in which the configuration of the first pattern P1 of the template 210 is inverted is formed in the first region R1 of the major surface 10a of the substrate 10. In the second pattern P2, the convex portion P2a that is inverse to the concave portion P1a of the first pattern P1 is formed at prescribed intervals.

The configuration of the second pattern P2 is inverse to the configuration of the first pattern P1 (the concavo-convex configuration of the pattern to be formed).

The concave portion P2b is formed between adjacent convex portions P2a of the second pattern P2. A thin film RLT of the resin 20 is formed at the bottom of the concave portion P2b. This is formed by the resin 20 interposed in the space between the template 210 and the major surface 10a.

In this processing, no pattern is formed in the second region R2 of the major surface 10a of the substrate 10.

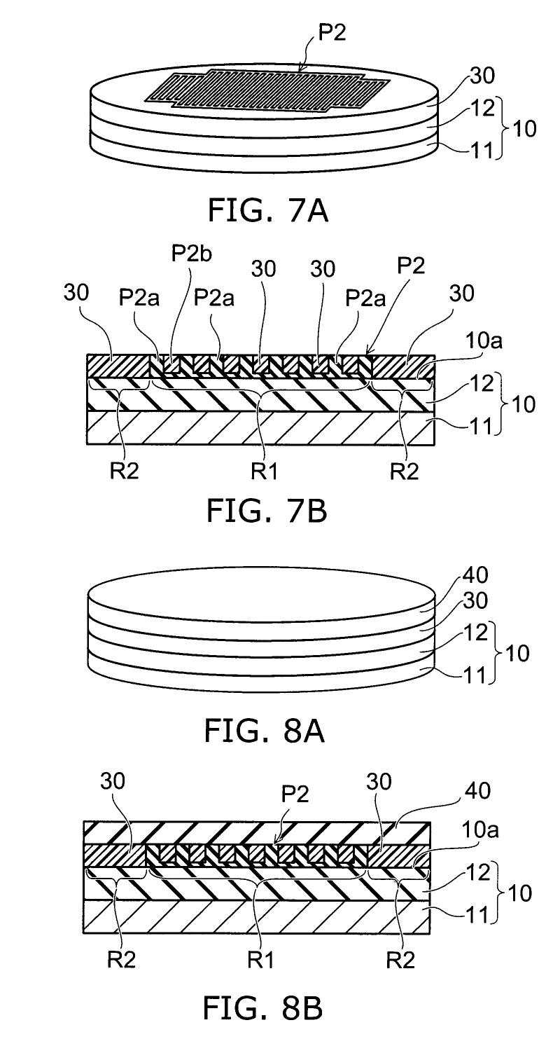

Next, as shown in steps S205 to S206 of FIG. 4 and FIGS. 7A and 7B, the second member 30 is formed.

FIG. 7A is a schematic perspective view, and FIG. 7B is a schematic cross-sectional view.

That is, the second member 30 is provided in the concave portion P2b of the second pattern P2 on the major surface 10a of the substrate 10 and in the second region 2. The second member 30 is, for example, an organic substance containing silicon.

The second member 30 is put in around the second pattern P2. The second member 30 is, for example, put in so as to cover the entire second pattern P2. After that, the second member 30 is ground until the second pattern P2 becomes exposed. The surface at which the second pattern P2 is exposed is planarized.

Next, as shown in step S207 of FIG. 4 and FIGS. 8A and 8B, a photosensitive member 40 is formed.

FIG. 8A is a schematic perspective view, and FIG. 8B is a schematic cross-sectional view.

That is, the photosensitive member 40 is formed on the second member 30 formed on the major surface 10a side of the substrate 10. The photosensitive member 40 is uniformly applied onto the second member 30 by, for example, the spin coating method.

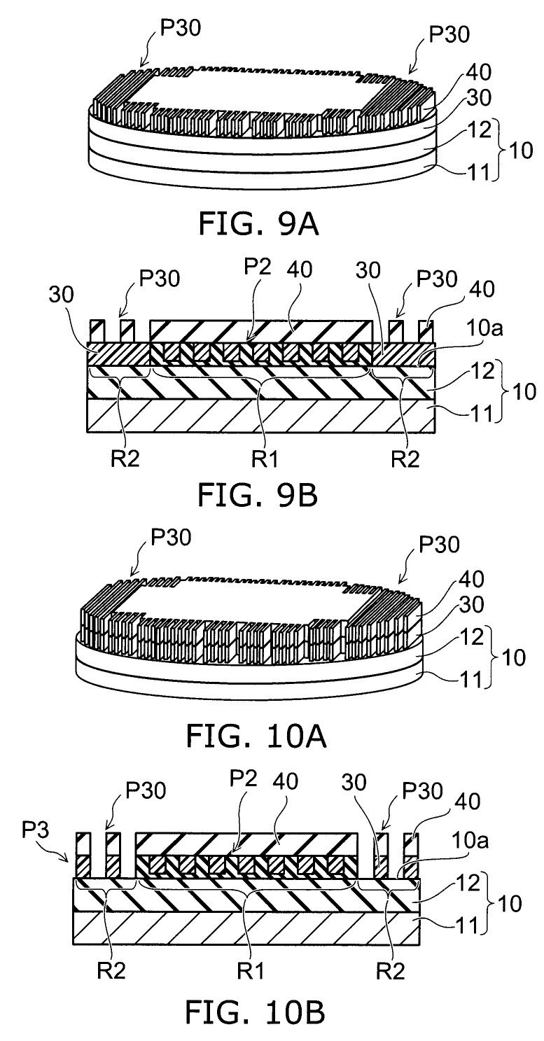

Next, as shown in step S208 of FIG. 4 and FIGS. 9A and 9B, the third pattern P3 is formed.

FIG. 9A is a schematic perspective view, and FIG. 9B is a schematic cross-sectional view.

That is, optical lithography is performed on a portion of the photosensitive member 40 previously applied which overlaps with the second region R2 as viewed in the direction orthogonal to the major surface 10a. Thereby, a mask pattern P30 is formed. The mask pattern P30 is formed in the region corresponding to the partial chip portion. Since the mask pattern P30 is formed using optical lithography, the mask pattern P30 is formed with good accuracy even in the partial chip portion.

Here, as viewed in the direction orthogonal to the major surface 10a, no pattern is formed in a portion of the photosensitive member 40 overlapping with the first region R1.

Next, as shown in step S209 of FIG. 4 and FIGS. 10A and 10B, the second member 30 is etched.

FIG. 10A is a schematic perspective view, and FIG. 10B is a schematic cross-sectional view.

That is, the second member 30 underlying is etched via the mask pattern P30 previously formed. The second member 30 is etched by, for example, anisotropic RIE (reactive ion etching). By the etching, the third pattern P3 is formed in the second member 30. The film to be processed 12 is exposed between portions of the third pattern P3.

Since the second pattern P2 on the first region R1 is protected by the photosensitive member 40, the second pattern P2 is not etched.

Next, as shown in step S210 of FIG. 4 and FIG. 11A to FIG. 12B, the photosensitive member 40 and the second pattern P2 are removed.

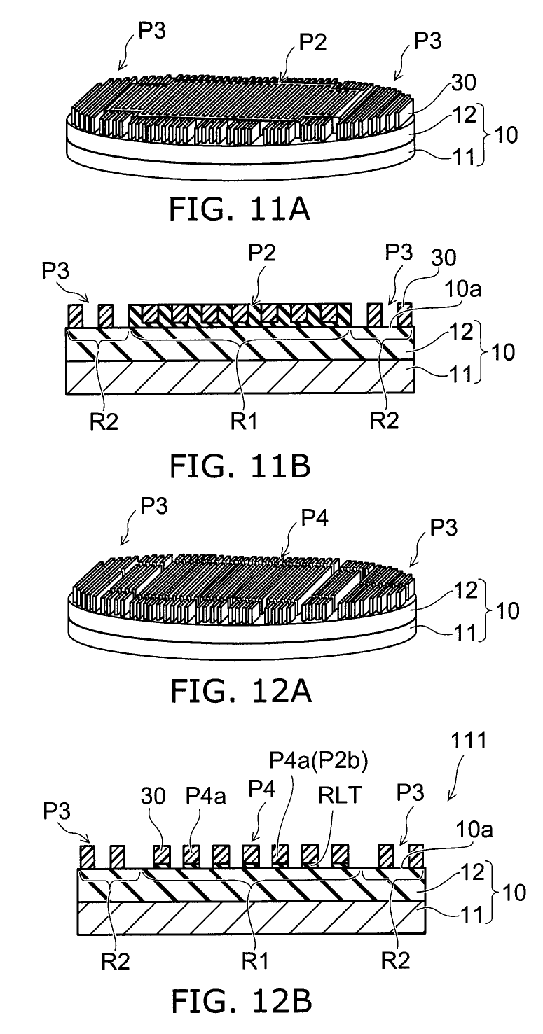

FIG. 11A is a schematic perspective view, and FIG. 11B is a schematic cross-sectional view.

FIGS. 11A and 11B show the state after the photosensitive member 40 shown in FIGS. 10A and 20B is removed.

The photosensitive member 40 is removed by, for example, wet etching.

Furthermore, as shown in FIGS. 12A and 12B, the second pattern P2 is removed.

FIG. 12A is a schematic perspective view, and FIG. 12B is a schematic cross-sectional view.

The processes from the removal of the photosensitive member 40 shown in FIGS. 11A and 11B to the removal of the second pattern P2 shown in FIGS. 12A and 12B may be collectively performed. That is, the same material is selected as the material of the photosensitive member 40 and the material of the second pattern P2. Alternatively, the photosensitive member 40 and the second pattern P2 are made of materials that can be removed by the same etchant. Thereby, they can be collectively removed by the same etchant.

Here, the etching rate of the first member forming the second pattern P2 to an etchant is higher than the etching rate of the second member 30 to the etchant. Therefore, in the etching, only the second pattern P2 is removed.

When the second pattern P2 has been removed, the second member 30 provided in the concave portion P2b of the second pattern P2 remains as a convex pattern P4a. The convex pattern P4a forms the fourth pattern P4. The fourth pattern P4 is formed on the first region R1. The fourth pattern P4 includes the thin film RLT that is the first member interposed between the major surface 10a and the second member 30. The film to be processed 12 is exposed between adjacent portions of the convex pattern P4a of the fourth pattern P4.

The third pattern P3 remains on the second region R2.

The coverage ratio of the third pattern P3 is equal to the coverage ratio of the mask pattern P30 shown in FIGS. 10A and 10B. On the other hand, the coverage ratio of the fourth pattern P4 is equal to the coverage ratio of the first pattern P1 (see FIGS. 6A to 6D). The coverage ratio of the third pattern P3 is preferably made equal to the coverage ratio of the fourth pattern P4.

Next, as shown in step S211 of FIG. 4, the film to be processed 12 is etched.

That is, the third pattern P3 and the fourth pattern P4 are used as a mask to etch the film to be processed 12 underlying.

The film to be processed 12 is removed by, for example, RIE. After the film to be processed 12 is etched, the third pattern P3 and the fourth pattern P4 that have been used as a mask are removed.

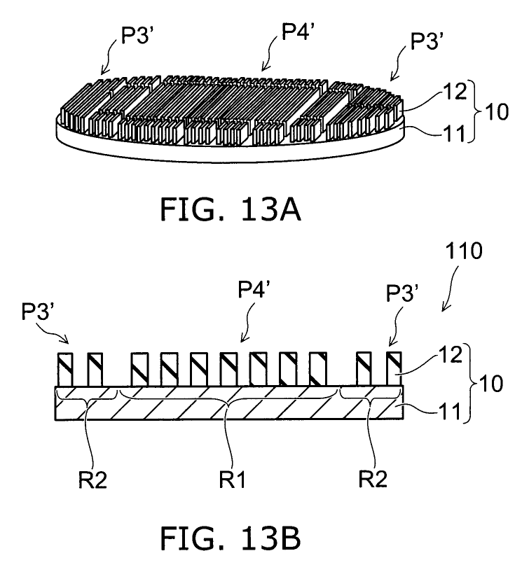

FIGS. 13A and 13B show the state after the third pattern P3 and the fourth pattern P4 are removed.

FIG. 13A is a schematic perspective view, and FIG. 13B is a schematic cross-sectional view.

When the film to be processed 12 has been etched using the third pattern P3 and the fourth pattern P4 as a mask, a third concavo-convex portion P3′ and a fourth concavo-convex portion P4′ that reflect the configurations of the third pattern P3 and the fourth pattern P4, respectively, are formed. Thereby, a desired pattern is formed (step S212 of FIG. 4).

The fourth concavo-convex portion P4′ is formed on the first region R1 with an accuracy by what is called the imprint method. The third concavo-convex portion P3′ is formed on the second region R2 with an accuracy by the optical lithography method. The coverage ratio of the third concavo-convex portion P3′ reflects the coverage ratio of the third pattern P3. The coverage ratio of the fourth concavo-convex portion P4′ reflects the coverage ratio of the fourth pattern P4.

Thus, the fourth concavo-convex portion P4′ can be formed in the first region R1, and further the third concavo-convex portion P3′ can be formed in the second region R2 by what is called the imprint method. Thereby, uniformity can be increased in a subsequent etching process and a process such as CMP.

Furthermore, in the embodiment, only the mask for exposure used in forming the mask pattern P30 is needed as the mask for exposure used in optical lithography as shown in FIGS. 9A and 9B. Thereby, even in the case where optical lithography is combined with what is called the imprint method, the number of optical shots can be made the minimum necessary level, and this makes it possible to achieve the simplification of the manufacturing processes and the reduction of the manufacturing time.

### Third Embodiment

A third embodiment is a method for manufacturing an electronic device.

The method for manufacturing an electronic device according to the embodiment includes a process that forms a pattern using the pattern formation methods according to the first and second embodiments describe above.

That is, the method for manufacturing an electronic device according to the embodiment includes a process in which the third pattern P3 and the fourth pattern P4 are formed by the pattern formation method shown in FIG. 4 and FIGS. 5A to FIG. 13B, and in which the patterns are used as the pattern of an objective or used to form the pattern of another objective (e.g. the third concavo-convex portion P3′ and the fourth concavo-convex portion P4′). The electronic device is an element having various functions of an active element such as a transistor and a diode, a passive element such as a resistance and a capacitor, etc.

The third embodiment provides a manufacturing method in which an electronic device can be manufactured with good accuracy in a short time using what is called the imprint method.

### Fourth Embodiment

A fourth embodiment is an electronic device. FIGS. 13A and 13B show an electronic device 110 that is an example of the embodiment. The electronic device 110 is an element having various functions of an active element such as a transistor and a diode, a passive element such as a resistance and a capacitor, etc. The electronic device 110 includes the third concavo-convex portion P3′ and the fourth concavo-convex portion P4′ formed in the film to be processed 12 of the substrate 10. The third concavo-convex portion P3′ and the fourth concavo-convex portion P4′ are used as part of the element having various functions.

The fourth embodiment provides an electronic device 110 with high accuracy which can be manufactured in a short time using what is called the imprint method.

As described above, the pattern formation method according to the embodiment can provide a highly reliable device using the formation of a pattern by what is called the imprint method.

Hereinabove, the embodiments and modification examples thereof are described. However, the invention is not limited to these examples. For example, one skilled in the art may appropriately make additions, removals, and design changes of components to the embodiments or the modification examples thereof described above, and may appropriately combine features of the embodiments; such modifications also are included in the scope of the invention to the extent that the spirit of the invention is included.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A pattern formation method comprising:
providing a first member on a major surface of a substrate and curing the first member in a state of a template having a first pattern being brought into contact with the first member to form a second pattern including a convex portion with a configuration inverse to a configuration of the first pattern in a first region on the major surface;
providing a second member in a concave portion adjacent to a convex portion of the second pattern on the major surface and in a second region around the first region;
forming a third pattern in the second member provided in the second region on the major surface; and
removing the convex portion of the second pattern to leave the third pattern and a fourth pattern formed by the second member provided in the concave portion on the major surface.

2. The method according to claim 1, further comprising etching the substrate using the third pattern and the fourth pattern as a mask.

3. The method according to claim 1, wherein a concavo-convex configuration of the second pattern is inverse to a concavo-convex configuration of the fourth pattern.

4. The method according to claim 1, wherein the fourth pattern has a configuration in which the entire first pattern is transferred.

5. The method according to claim 1, wherein the third pattern is a concavo-convex pattern corresponding to part of the first pattern.

6. The method according to claim 1, wherein the second pattern is removed by etching with an etchant.

7. The method according to claim 1, wherein the second pattern is removed by wet etching.

8. The method according to claim 1, wherein a coverage ratio of the third pattern is equal to a coverage ratio of the fourth pattern.

9. The method according claim 1, wherein the fourth pattern includes the first member interposed between the major surface and the second member.

10. The method according to claim 1, wherein the first member is a photocurable resin.

11. The method according to claim 1, wherein the second member is an organic substance containing silicon.

12. The method according to claim 1, wherein the substrate contains silicon oxide.

13. A method for manufacturing an electronic device comprising:
forming a pattern using a pattern formation method including:
providing a first member on a major surface of a substrate and curing the first member in a state of a template having a first pattern being brought into contact with the first member to form a second pattern including a convex portion with a configuration inverse to a configuration of the first pattern in a first region on the major surface;
providing a second member in a concave portion adjacent to a convex portion of the second pattern on the major surface and in a second region around the first region;
forming a third pattern in the second member provided in the second region on the major surface; and
removing the convex portion of the second pattern to leave the third pattern and a fourth pattern formed by the second member provided in the concave portion on the major surface.

14. The method according to claim 13, further comprising etching the substrate using the third pattern and the fourth pattern as a mask.

15. The method according to claim 13, wherein a concavo-convex configuration of the second pattern is inverse to a concavo-convex configuration of the fourth pattern.

16. The method according to claim 13, wherein the fourth pattern has a configuration in which the entire first pattern is transferred.

17. The method according to claim 13, wherein the third pattern is a concavo-convex pattern corresponding to part of the first pattern.

18. The method according claim 13, wherein the fourth pattern includes the first member interposed between the major surface and the second member.

19. An electronic device comprising:
a pattern formed using a pattern formation method including:
providing a first member on a major surface of a substrate and curing the first member in a state of a template having a first pattern being brought into contact with the first member to form a second pattern including a convex portion with a configuration inverse to a configuration of the first pattern in a first region on the major surface;
providing a second member in a concave portion adjacent to a convex portion of the second pattern on the major surface and in a second region around the first region;
forming a third pattern in the second member provided in the second region on the major surface; and
removing the convex portion of the second pattern to leave the third pattern and a fourth pattern formed by the second member provided in the concave portion on the major surface.

20. The electronic device according to claim 19, wherein the fourth pattern includes the first member interposed between the major surface and the second member.
